(19) United States
(12) Patent Application Publication
(10) Pub. No.: US 2013/0011581 A1
(43) Pub. Date: Jan. 10, 2013

(54) PROTECTIVE DEVICE FOR ELECTRODE HOLDERS IN CVD REACTORS

(75) Inventors: Barbara Müller, Erlbach (DE); Heinz KRAUS, Zeilarn (DE); Elmar MONZ, Marktl (DE); Mikhail SOFIN, Grobenhain (DE)

(73) Assignee: WACKER CHEMIE AG, Muenchen (DE)

(21) Appl. No.: 13/535,844

(22) Filed: Jun. 28, 2012

(30) Foreign Application Priority Data
Jul. 6, 2011 (DE) 102011078727.5

(51) Int. Cl. B05C 13/02; C23C 16/24

(52) U.S. Cl. 427/588; 118/500

(57) ABSTRACT

A device for protecting electrode holders in CVD reactors includes an electrode suitable for accommodating a filament rod on an electrode holder which includes an electrically conductive material and is installed in a recess of a bottom plate, wherein an intermediate space between an electrode holder and a bottom plate is sealed by means of a sealing material, and the sealing material is protected by a protective body which is made up of one or more parts and is arranged in a ring-like manner around the electrodes, and the height of the protective body increases at least in sections in the direction of the electrode holder.

### BACKGROUND

The invention relates to a device for protecting electrode holders in CVD reactors.

High-purity polycrystalline silicon (polysilicon) is generally produced by means of the Siemens process.

Here, a reaction gas containing one or more silicon-containing components and optionally hydrogen is introduced into a reactor containing support bodies which are heated by direct passage of electric current and on which silicon deposits in solid form.

As silicon-containing compounds, preference is given to using silane (SiH₄), monochlorosilane (SiH₃Cl), dichlorosilane (SiH₂Cl₂), trichlorosilane (SiHCl₃), tetrachlorosilane (SiCl₄) or mixtures thereof.

Each support body usually comprises two thin filament rods and a bridge which generally connects adjacent rods at their free ends. The filament rods are most frequently made of monocrystalline or polycrystalline silicon; metals or alloys or carbon are used less often. The filament rods are plugged vertically into electrodes located on the bottom of the reactor and the connection to the electrode holder and power supply is effected via these electrodes. High-purity polysilicon deposits on the heated filament rods and the horizontal bridge, as a result of which the diameter of these increases with time. After the desired diameter has been reached, the process is stopped.

The silicon rods are held in the CVD reactor by special electrodes which generally comprise graphite. Two thin rods in each case having different electric polarities on the electrode holders are at the other end of the thin rod connected by a bridge to a closed electric circuit. Electric energy is supplied by the electrodes and their electrode holders for heating the thin rods. As a result, the diameter of the thin rods increases. At the same time, the electrode grows, starting at its tip, into the rod base of the silicon rods. After a desired nominal diameter of the silicon rods has been attained, the deposition process is stopped, the silicon rods are cooled and removed from the reactor.

Protection of the electrode holder running through the bottom plate and the surrounding seal is of particular importance here. Since the trend is toward ever longer and thicker rods in shorter deposition cycles, the arrangement and shape of the electrode seal protective bodies and also the material of the seal to be protected are of importance. This is because the possible yield and/or quality-influencing malfunctions in the process of deposition of polysilicon can be avoided by means of an optimized arrangement. Possible malfunctions in the deposition process which influence the yield or quality include, for example, electric power failures due to ground fault during deposition. This malfunction reduces the output because the process is stopped prematurely.

Depending on the later use of the silicon rods produced in this way, the silicon rods and the deposition process and thus the electrode holder and the protection thereof have to meet very different requirements. If, for example, the polycrystalline silicon is used later in silicon fragments for solar and electronic applications, the silicon rods must not fall over in the deposition reactor or be contaminated by foreign materials coming from, for example, sealing materials which come into contact with the product during or after the deposition process. Long and thick polycrystalline silicon rods increase the economics of the deposition process, but also the risk of falling over in the reactor.

The WO 2010/083899 A1 discloses an electrode protection device according to the prior art. Here, thin rods in a graphite adapter which engages in a graphite clamping ring which in turn interacts via a fused silica ring with the bottom plate of the CVD reactor for producing polycrystalline silicon via the monosilane process are described.

In the prior art, attempts have been made to solve the problems of electric power failures by sealing and insulating the electrode passed through the bottom plate.

Shielding the seals of the electrodes against thermal stress by means of protective rings made of fused silica is known from WO 2010/083899 A1.

DE 23 28 303 A1 describes an apparatus for producing rods and tubes composed of silicon by deposition of the semiconductor material concerned from the gas phase onto the outer surface of a heated elongated support, in particular a support composed of silicon or graphite, which comprises a reaction vessel having a bottom plate made of metal and at least one electrode which holds an end of the elongated support and serves for heating the support and is conducted through the bottom plate in an electrically insulated and sealed manner, characterized in that a first electrode part consisting of metal is fastened in the bottom plate with insertion of a sealing layer of inert, insulating material, in particular tetrafluoropolyethylene, and has a projection which projects into the reaction space and on which a further electrode part consisting of metal or carbon and having a fitting area for accommodating and holding the support on its free surface rests exchangeably.

A first part of the electrode holder, which consists of metal, is thus fastened in the bottom plate with insertion of a sealing layer of inert insulating material.

JP 2009-221058 A2 discloses a seal and insulation by use of a specific zirconium ceramic, of flexible graphite and coated O-rings as a seal. Such materials are resistant to high temperatures and make sealing of the gap between electrodes and bottom plate possible.

WO 2010/068849 A1 describes an improved thermal insulation in the region of the passage of the electrodes through the bottom plate by use of a metal body which is provided with an insulating surface coating.

However, the devices known hitherto do not disclose sufficient protection of the seal of the electrode holders. As a result, the probability of failure due to corrosion effects and ground fault is increased. In addition, no sufficient protection of the seal against corrosion and thus discharge of materials which influence the product quality (especially dopants) has hitherto been found.

It is an object of the invention to provide a device which significantly reduces these effects.

### BRIEF SUMMARY OF THE INVENTION

The object of the invention is achieved by a device for protecting electrode holders in CVD reactors, which comprises an electrode suitable for accommodating a filament rod on an electrode holder which is composed of an electrically conductive material and is installed in a recess of a bottom plate, wherein an intermediate space between electrode holder and bottom plate is sealed by means of a sealing material and the sealing material is protected by a protective body which is made up of one or more parts and is arranged in a ring-like manner around the electrodes and the height of the protective body increases at least in sections in the direction of the electrode holder.

The object is likewise achieved by a process for producing polycrystalline silicon, which comprises introducing a reaction gas containing a silicon-containing component and hydrogen into a CVD reactor containing at least one filament rod which is located on one of the above mentioned devices, is supplied with electric power by means of the electrode and is thus heated by direct passage of electric current to a temperature at which silicon deposits on the filament rod.

The protective body of the device of the invention is preferably configured so that, during operation of the CVD reactor, reaction gases are guided to the lower part of the filament, hereinafter referred to as rod base, located on the electrode. This can, for example, be brought about by the protective body having one or more protective rings which are arranged concentrically around the electrodes and individually or together increase in height in the direction of the electrodes, so that reaction gas flowing in from a gas inlet opening or nozzle of the reactor is guided to the rod base by the geometry of the protective rings.

The optimal geometry of the protective body thus depends on the height of the electrode holder and the length of the electrode. Preferred dimensions of the electrode-protecting body are: diameter: 50-250 mm, particularly preferably 100-170 mm, height: 20-100 mm, particularly preferably 20-70 mm, thickness: 10-100 mm, particularly preferably 10-50 mm. The slope of the geometric protective bodies used individually or in combination is preferably 30°-60°, particularly prefer-ably 40°-50°.

This arrangement of the protective body allows rapid and uniform growth of silicon on the rod base. It has been found that the nonuniform growth of silicon which is often observed in the prior art and can lead to the filament falling over can largely be prevented in this way, i.e. a reduction in the incidence of falling-over is achieved.

It is known that charges which have fallen over represent a large economic loss. Thus, for example, falling-over of the silicon rods can lead to damage to the reactor wall. The silicon rods which have fallen over are contaminated in the process by contact with the reactor and have to be cleaned on the surface. In addition, charges which have fallen over can be removed from the reactor only with increased difficulty. During this, the surface of the silicon is contaminated further.

The invention thus provides for the use of optimized protective bodies for seals and insulations on electrode holders.

The protective bodies have been optimized in respect of their geometry and the material used and also in respect of their arrangement on the bottom plate.

Apart from the pure protective function for the seal used against direct irradiation, the flow of gas in the reaction space in relation to the seal and rod bases is also influenced positively in thermal terms, especially since the seals are subjected to a lower temperature.

Scorching of the sealing and insulating bodies even in the case of relatively large seal dimensions and failure due to ground fault and the reactor not being sealed against the environment and also introduction of dopants into the system are therefore less probable.

Furthermore, it was observed that surface treatment of the protective rings significantly reduces the frequency of ground fault.

It was essential to the success of the invention to provide geometric bodies in a concentric arrangement around the electrode lead-through and the current-conducting electrodes.

Not only thermal protection of the sealing and insulating body of the electrode holder against the bottom plate but also modification of the flow at the rod base of the deposited polysilicon rods are achieved by means of such an arrangement.

Corrosive effects at the sealing and insulating ring which were observed in the prior art when using an unoptimized protective body no longer occur when the optimized protective body is used.

An embodiment of the invention provides for a plurality of rings to be arranged concentrically around the electrode holder, with the height of the rings decreasing with increasing radius of the rings and an additional protective ring having a smaller radius than the other protective rings being provided in a recess between electrode and bottom plate. This additional protective ring preferably comprises two half rings, c.f. FIG. 7A.

Preference is thus given to a ring having the greatest height being provided in the vicinity of the electrode, with the height of the further rings decreasing with increasing distance from the electrode.

This embodiment of the invention provides a plurality of rings, i.e. a plurality of individual bodies.

However, preference is also given, in the second embodiment of the invention, to providing a single geometric body, with in the case of this body, too, the height decreasing with increasing distance from the electrode holder.

The use of geometric bodies of any shape is also preferred, as long as one end of the body is higher than the other end of the body.

The rings or bodies used can rest on the bottom plate of the reactor.

Preference is likewise given to the rings or bodies being partly sunk into the bottom plate.

The rings or bodies preferably comprise translucent silica (capable of passing wavelengths of 300-10 000 nm with a spectral transmission of up to 1%), silver, silicon (polycrystalline and/or monocrystalline), tungsten carbide, Si carbide, silicon-coated graphite, carbon fiber-reinforced carbon (CFC) composites, tungsten or other high-melting metals.

Owing to the high thermal stress, the growing of a thin silicon layer over the protective bodies during the CVD process is very particularly preferred. The surface of the geometric body can be untreated or pretreated over its entirety or in individual compartments. It has been found to be advantageous to pretreat at least the surfaces of the protective ring having the smallest diameter, which is located in the vicinity of the electrodes, so that in a roughness measurement (Ra arithmetic mean; parameter in accordance with DIN EN ISO 4287), Ra=10-40 μm is achieved.

Preference is given to using protective bodies having a Ra of 15-30 μm; particular preference is given to an Ra of 16-25 μm.

When protective bodies are used, they can also be cast parts composed of silver.

The shaped bodies can be used one or more times in deposition of polycrystalline silicon by the Siemens process. The shaped bodies can be brushed off or cleaned wet or dry before use.

Both embodiments of the invention provide good screening of electrode and seal and also effect local optimization of the gas flow.

The shaped bodies used can essentially be handled easily.

The reactor comprises a plurality of U-shaped filaments on which polycrystalline silicon can be deposited.

For this purpose, reaction gas comprising a silicon-containing compound is introduced by means of nozzles into the reactor. The filaments are supplied with electric power by means of a voltage connection and heated to a deposition temperature.

The reactor comprises a reactor bottom. A plurality of electrodes for accommodating the filaments are installed on this reactor bottom.

The device of the invention is preferably used in the deposition of polysilicon in a CVD reactor.

The electrode holder comprises electrically conductive metals, preferably one or more materials selected from the group consisting of brass, silver and copper and combinations thereof.

The invention is illustrated below with the aid of figures.

### BRIEF DESCRIPTION OF THE DRAWINGS

FIG. 1 schematically shows the lead-through through the bottom plate of a CVD reactor required for supplying electric power and the associated electrodes.

FIG. 2 schematically shows two embodiments 2A and 2B of an electrode arrangement with protective body.

FIG. 3 shows an electrode arrangement having multipart concentrically arranged protective bodies.

FIG. 4 shows a device having a one-piece protective body.

FIG. 5 shows an electrode arrangement having only one protective ring.

FIG. 6 shows an arrangement as in FIG. 4 with plan view.

FIG. 7 shows embodiments 7A, 7B and 7C for divided protective rings.

FIG. 8 shows an embodiment comprising a combination of a plurality of rings of increasing height and half rings pushed under the electrodes.

### LIST OF REFERENCE NUMERALS USED

1 Bottom plate
2 Electrode holder
3 Sleeve
4 Seal
5 Protective ring

### DETAILED DESCRIPTION OF THE INVENTION

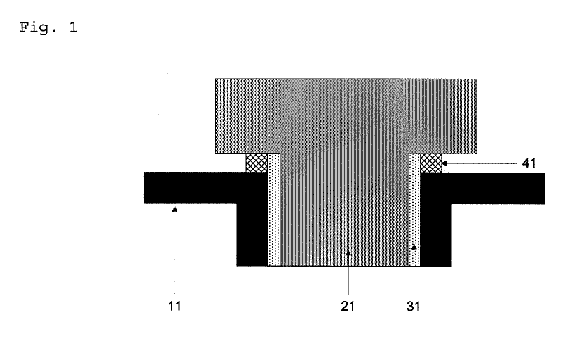

FIG. 1 shows the metallic bottom plate 11 of a reactor and an electrode holder 21.

The bottom plate 11 is provided with a hole which is lined with a sleeve 31 and through which an electrode holder 21 is passed and fitted in a gastight manner.

The intermediate space between the electrode holder 21 and the bottom plate 11 is sealed by means of a seal 41, preferably made of polytetrafluoroethylene (PTFE). The sleeve 31 also preferably consists of PTFE.

PTFE seals, mica seals having a PTFE contact surface and PTFE seals containing a proportion of 30-40% of silicon dioxide have been found to be suitable as materials for the seal 41. Seals made of a restructured PTFE sealing material have been found to be particularly suitable.

Electrode holder 21 preferably comprises one or more materials selected from the group consisting of brass, silver and copper.

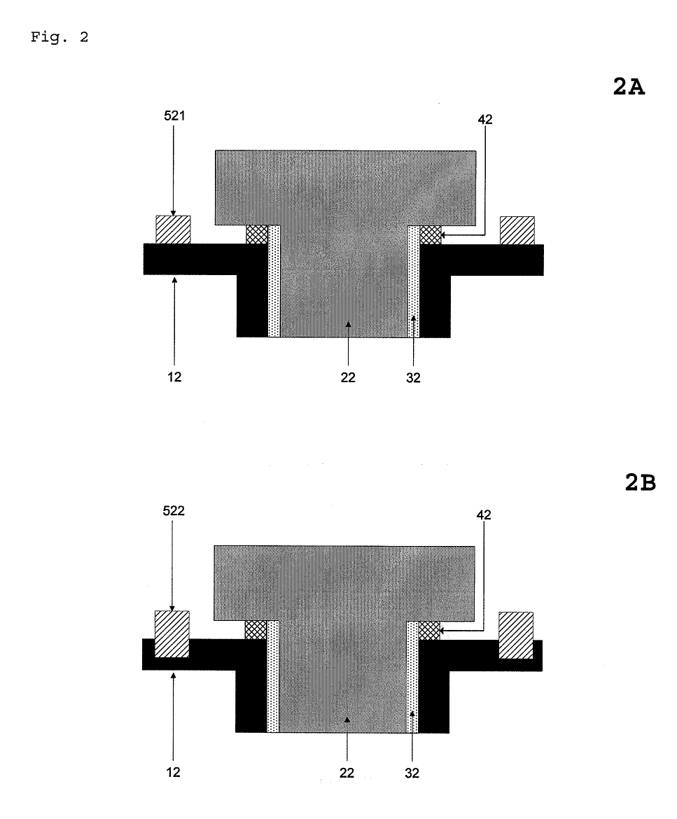

FIG. 2 shows two embodiments for the installation of protective rings.

52 denotes a protective ring made of silica arranged around an electrode holder 22.

2A shows a protective ring 521 resting on the bottom plate 12.

2B shows a protective ring 522 which is partly sunk into the bottom plate 12.

FIG. 3 shows a plurality of protective rings 531 which are preferably arranged concentrically around the electrode holder 23. The protective rings 531 rest on the bottom plate 13.

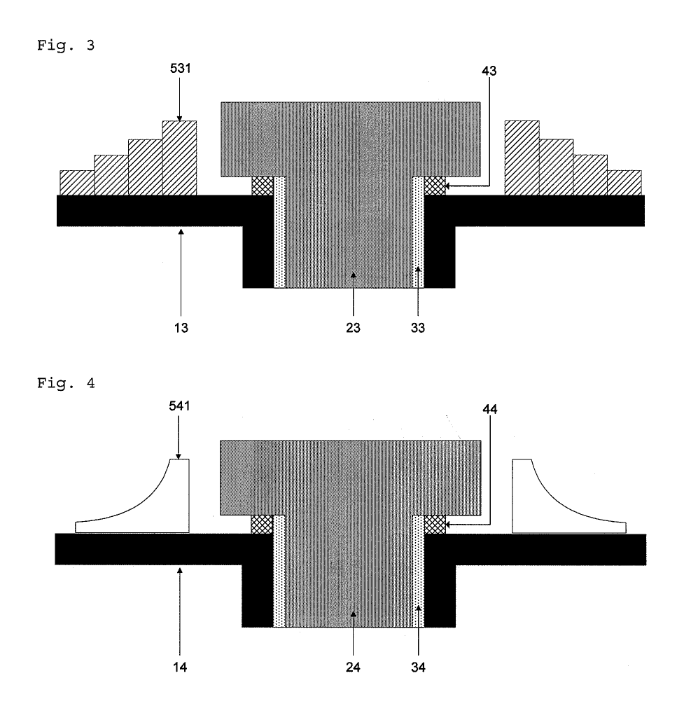

FIG. 4 shows an embodiment for one-piece protective rings.

A protective ring 541 which is arranged next to the electrode holder 24 and decreases in height with increasing distance from the electrode holder 24. The maximum height of the protective ring 541 corresponds approximately to the upper end of the electrode holder 24 or goes slightly beyond this. The protective ring 541 rests on the bottom plate 14. 44 denotes the seal to be protected.

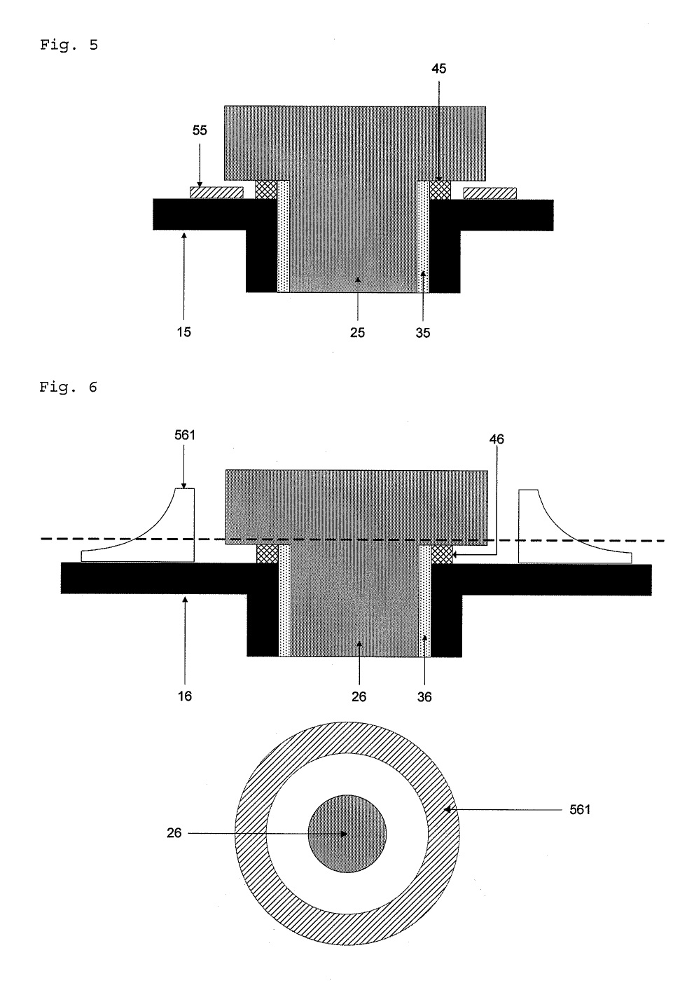

FIG. 5 shows a protective ring 55 pushed between bottom plate 15 and electrode 25. Protective ring 55 is made in one piece and rests on the bottom plate 15.

FIG. 6 shows an electrode arrangement corresponding to

FIG. 4 and also a plan view of the arrangement. This makes it clear that the arrangement is annular.

16 denotes the bottom plate on which the protective ring 561 rests.

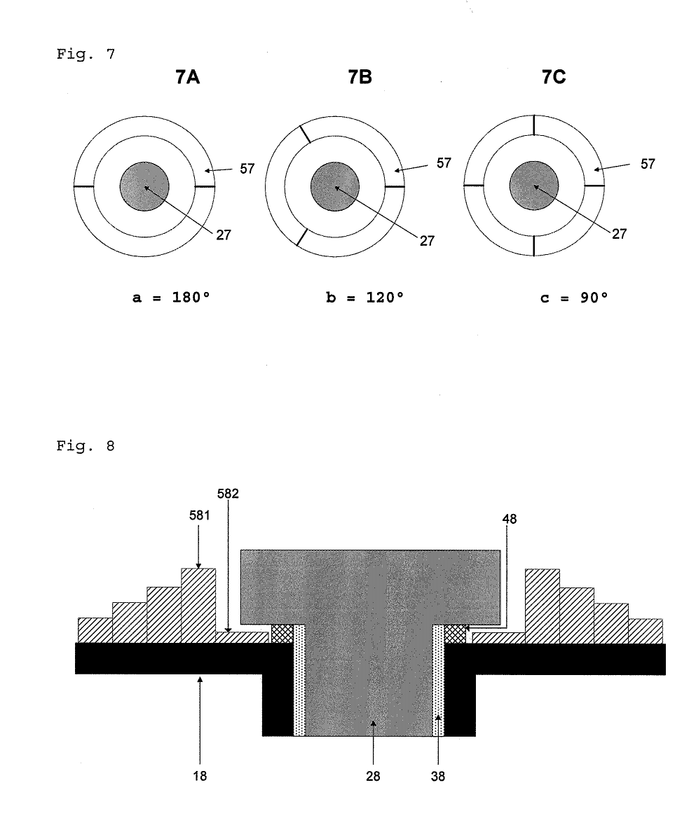

FIG. 7 likewise shows plan views of three embodiments of electrode arrangements.

27 denotes the electrode holder, 57 in each case represents the protective ring.

Protective ring 57 is in each case divided.

7A shows a protective ring 57 which is divided twice (angle 180°).

7B shows a protective ring 57 which is divided three times (angle 120°).

7C shows a protective ring 57 which is divided four times (angle 90°).

FIG. 8 shows an embodiment having a combination of a plurality of rings 581 of increasing height and half rings pushed under the electrode holder 28.

What is claimed is:

1. A device for protecting electrode holders in CVD reactors, comprises an electrode suitable for accommodating a filament rod on an electrode holder which includes an electrically conductive material and is installed in a recess of a bottom plate, wherein an intermediate space between the electrode holder and the bottom plate is sealed by means of a sealing material and the sealing material is protected by a protective body which is made up of one or more parts and is arranged in a ring-like manner around the electrode and the height of the protective body increases at least in sections in the direction of the electrode holder.

2. The device as claimed in claim 1, wherein the protective body is made up of a plurality of parts which are arranged concentrically around the electrode holder.

3. The device as claimed in claim 1, wherein the material of the protective body is selected from the group consisting of translucent silica, silver, monocrystalline or polycrystalline silicon, tungsten carbide, silicon carbide, silicon-coated graphite, CFC composites, tungsten and other high-melting metals.

4. The device as claimed in claim 1, wherein the protective body comprises at least partly translucent silica or silver.

5. The device as claimed in claim 1, wherein the protective body is made up of a plurality of parts of which at least one comprises translucent silica or silver.

6. The device as claimed in claim 1, wherein the sealing material is additionally protected by a protective body arranged in a ring-like manner around the electrode holder in the intermediate space between the electrode holder and the bottom plate.

7. A process for producing polycrystalline silicon, which comprises introducing a reaction gas containing a silicon-containing component and hydrogen into a CVD reactor containing at least one filament rod which is located on a device as claimed in claim 1, is supplied with electric power by means of the electrode and is thus heated by direct passage of an electric current to a temperature at which silicon deposits on the filament rod.
